(19) United States
(12) Patent Application Publication
(10) Pub. No.: US 2009/0120457 A1
(43) Pub. Date: May 14, 2009

(54) COMPOSITIONS AND METHOD FOR REMOVING COATINGS AND PREPARATION OF SURFACES FOR USE IN METAL FINISHING, AND MANUFACTURING OF ELECTRONIC AND MICROELECTRONIC DEVICES

(75) Inventors: Shahriar Naghshineh, Allentown, PA (US); Kevin Yanders, Germansville, PA (US); Ewa Oldak, Fountain Hill, PA (US); George Schwartzkopf, Washington, NJ (US)

Correspondence Address: DESIGN IP, P.C., 5100 W. TILGHMAN STREET, SUITE 205, ALLENTOWN, PA, 18104, US

(73) Assignee: SURFACE CHEMISTRY DISCOVERIES, INC., Bethlehem, PA (US)

(21) Appl. No.: 12/266,954

(22) Filed: Nov. 7, 2008

Related U.S. Application Data
(60) Provisional application No. 61/002,598, filed on Nov. 9, 2007.

(51) Int. Cl. C23G 1/14; G03F 7/42

(52) U.S. Cl. 134/2; 510/176

(57) ABSTRACT

Improved cleaning compositions for removing particles, organic contamination, photoresist, post-ash residue, coatings, and other materials from metal and silicon surfaces including substrates present during the manufacture of integrated circuits, liquid crystal displays, and photovoltaic devices. The cleaning and surface preparation compositions comprise one or more water soluble strongly basic components, one or more water soluble organic amines, one or more water soluble oxidizing agents, balance water. Optional components can include corrosion inhibitors, surfactants and chelating agents.

### CROSS REFERENCE TO RELATED APPLICATION(S)

This application claims priority from U.S. Patent Application No. 61/002,598 filed Nov. 9, 2007, which is incorporated by reference as if fully set forth.

### FIELD OF INVENTION

The present invention pertains to removing particles, organic contamination, photoresist, post-ash residue, coatings, and other materials from metal and silicon surfaces including substrates present during the manufacture of integrated circuits, liquid crystal displays, and photovoltaic devices.

### BACKGROUND OF THE INVENTION

The fabrication of integrated circuits (IC) and other electronic devices such as photovoltaic cells incorporates scores of cleaning sequences involving a large number of toxic, flammable, explosive, and environmentally hazardous chemicals. These include hydrogen fluoride, hydroxylamine, phenols, strong acids, and a broad range of organic solvents. Many of these cleaning agents are also widely used for metal surfaces in variety of applications including exterior aircraft cleaning, metal parts degreasing, and engine maintenance.

An integral part of microelectronic fabrication is the use of photoresists to transfer an image from a mask or reticle to the desired circuit layer. After the desired image transfer has been achieved, the photoresist is removed by “stripping” before proceeding to some subsequent process step. A wide variety of photoresist compositions must be removed in this way. These include highly ion implanted positive photoresists that are present during IC gate fabrication and also the very thick negative photoresists used for solder bump placement. Typically, organic solvent mixtures are utilized for this photoresist removal step.

Alternatively, the bulk of the photoresist may be removed by treating with a plasma. This “ashing” process typically utilizes an oxygen plasma. During an ashing process, any metal-containing residues are oxidized and made more difficult to remove. Thus the cleaning solvents used for this purpose additionally contain fluorides, hydroxylamine, phenols, or amines which are needed to effectively remove post-ash residue.

Modern integrated circuit (IC) manufacturing also utilizes multiple chemical mechanical polishing (CMP) steps for each device. The chemical mechanical polishing processes involve holding and rotating a thin, flat substrate of the semiconductor material against a wetted polishing surface under controlled chemical, pressure and temperature conditions. A chemical slurry containing a polishing agent, such as alumina or silica, is used as the abrasive material. Unfortunately, chemical mechanical polishing processes leave contamination on the surfaces of the semiconductor substrate, which, like photoresist, must be removed before further elaboration of the integrated circuit. Alkaline solutions based on ammonium hydroxide have been traditionally used in post-chemical mechanical polishing cleaning applications.

U.S. Pat. No. 5,863,344, discloses a cleaning solution for semiconductor devices containing tetramethyl ammonium hydroxide, acetic acid, and water. The solution preferably contains a volumetric ratio of acetic acid to tetramethyl ammonium hydroxide ranging from about 1 to about 50.

U.S. Pat. No. 5,597,420, discloses a post etch aqueous stripping composition useful for cleaning organic and inorganic compounds from a substrate that will not corrode or dissolve metal circuitry in the substrate. The aqueous composition contains preferably 70 to 95 wt % monoethanolamine and a corrosion inhibitor at about 5 wt % such as catechol, pyrogallol or gallic acid.

U.S. Pat. No. 5,466,389, discloses an aqueous alkaline cleaning solution for cleaning microelectronic substrates. The cleaning solution contains a metal ion-free alkaline component such as a quaternary ammonium hydroxide (up to 25 wt %), a nonionic surfactant (up to 5 wt %), and a pH-adjusting component, such as acetic acid, to control the pH within the range of 8 to 10.

U.S. Pat. No. 5,563,119 discloses a post etch aqueous stripping composition consisting of an alkanolamine, tetraalkyammonium hydroxide, and a corrosion inhibitor for cleaning organic residue from aluminized inorganic substrates.

U.S. Pat. No. 6,194,366 discloses post-CMP cleaners comprising a quaternary ammonium hydroxide, an alkanolamine, and a corrosion inhibitor.

U.S. Pat. No. 7,365,045 discloses cleaning solutions consisting of a quaternary ammonium hydroxide, an organic amine, and water with pH greater than 10.

Those concerned with the development of surface cleaning and preparation technology have continuously sought cleaning techniques that avoid the use of hazardous materials, e.g., solvents, phenols, hydroxylamine, fluorides, and other hazardous and environmentally unacceptable components.

### SUMMARY OF THE INVENTION

In accordance with the present invention, compositions and methods of use are provided for removing particles, organic contamination, photoresist, post-ash residue, coatings, and other materials from metal and silicon surfaces including substrates present during the manufacture of integrated circuits, liquid crystal displays, and photovoltaic devices. The cleaning and surface preparation compositions comprise one or more water soluble strongly basic components capable of producing a pH greater than 10, one or more water soluble organic amines, one or more water soluble oxidizing agents, and water. The compositions may optionally also contain corrosion inhibitors, surfactants, and chelating agents to further enhance performance. The method of the invention comprises contacting a coated substrate with a cleaning composition with optional heating and/or the application of sonic energy.

Cleaning compositions according to the present invention have very high water content (up to about 99.7 wt %) resulting in low cost cleaners that may be safely transported and dispensed, and the safe disposal of which may consist of discharge to an appropriate industrial drain without any additional pretreatment.

Compositions according to the present invention have the following advantages over compositions of the prior art, namely;
(a) have a high water concentration resulting in low cost and negligible environmental impact;
(b) are not subject to performance deviations caused by incidental water absorbed from the atmosphere or otherwise present;
(c) do not contain hydrofluoric acid or salts thereof,
(d) do not contain solvents classified as hazardous air pollutants (HAPs), such as glycol ethers;
(e) do not contain hydroxylamine, a widely used but hazardous component of a microelectronics cleaner;
(f) are useful for removing coatings, photopolymers and photoresists as required for a very wide range of lithographic processes including the removal of thick photopolymers from solder bumps;
(g) are useful for removing residues and particles from microelectronic substrates and nano-structures after etching and ashing;
(h) are useful for cleaning microelectronic substrates and nano-structures following chemical mechanical polishing (CMP);
(i) are useful for cleaning silicon photovoltaic substrates; and
(j) are useful for a variety of metal cleaning applications.

The ability of compositions according to the invention, which may contain greater than 99% water, to remove organic polymer photoresists is unexpected. Typically solvent mixtures are used for this purpose. The water content of such solvent mixtures must be minimized to maintain photoresist removal efficiency. With the compositions according to the present invention, photoresist removal is facilitated by the presence of the oxidizing component.

Compatibility of organic amines of the invention with strong oxidizing agents is also unexpected since the oxidation of amines to substituted hydroxylamines, nitrones, and the like is normally considered to be facile. Another unexpected but useful feature of the compositions of the invention is the reduced solder etch rates resulting from the inclusion of an oxidizing component. Yet another unexpected but useful feature of compositions according to the invention is the reduced silicon wafer etch rates resulting from the inclusion of the oxidizing component.

Therefore, in one aspect the present invention is a liquid cleaning composition for removing particles, organic contamination, photoresist, post-ash residue, coatings, and other materials from metal and silicon surfaces comprising 0.1 to 10% by volume of a water soluble strong base, 0.1 to 20% by volume water soluble organic amine, 0.1 to 10% by volume water soluble oxidizing agent, balance water.

In another aspect, the present invention is a method for cleaning contaminants being one of, particles, organic contamination, post-ash residue, coatings and other materials from metal and silicon surfaces comprising the steps of exposing a surface coating of one or more of said contaminants to a composition consisting of 0.1 to 10% by volume of a strong base, 0.1 to 20% by volume water soluble organic amine, 0.1 to 10% by volume water soluble oxidizing agent, balance water at a temperature of from 10° C. to 85° C. for a period of time from ten seconds to sixty minutes; and rinsing said surface in de-ionized water.

### BRIEF DESCRIPTION OF THE DRAWING(S)

FIG. 1A is a scanning electron microscope (SEM) photomicrograph of a patterned thick photopolymer resist with deposited solder bumps.

FIG. 1B is a SEM photomicrograph of the device of FIG. 1A after removal of the photoresist with a composition according to the present invention.

FIG. 2A is an optical photomicrograph of a patterned thin photoresist that was impossible to remove using typical solvent mixtures.

FIG. 2B is an optical photomicrograph of the device of FIG. 2A after stripping with a composition according to the present invention.

FIG. 3A is a SEM photomicrograph of a thick negative photoresist deposited onto under bump metal (UBM), patterned, and then deposited with a tin-lead eutectic solder giving solder bumps over UBM.

FIG. 3B is a SEM photomicrograph of the device of FIG. 3A after removal of the photoresist with a composition according to the present invention.

FIG. 4A is a SEM photomicrograph of a thick negative photoresist deposited onto under bump metal (UBM), patterned, and then deposited with a high lead solder giving solder bumps over UBM.

FIG. 4B is a SEM photomicrograph of the device of FIG. 4A after removal of the photoresist with a composition according to the present invention.

### DETAILED DESCRIPTION OF THE PREFERRED EMBODIMENT(S)

The present invention provides new aqueous compositions for stripping or cleaning metal and silicon surfaces including substrates present during the manufacture of integrated circuits, liquid crystal displays, and photovoltaic devices that comprise one or more water soluble strongly basic components capable of producing a pH greater than 10, preferably greater than 12, one or more water soluble organic amines, one or more water soluble oxidizing agents, and water. The compositions may optionally also contain corrosion inhibitors, surfactants, and chelating agents to further enhance performance. These compositions may be prepared by blending or mixing components of the composition according to any method known in the art.

Preferably, compositions according to the present invention comprise from about 0.1% to about 10% of water soluble strongly basic components, from about 0.1% to about 20% of water soluble organic amines, from 0.1% to about 10% of water soluble oxidizing agents, balance of water. More preferably, these compositions comprise from about 1% to about 10% of water soluble strongly basic components, from about 1% to about 10% of water soluble organic amines, from about 0.1% to about 5% of water soluble oxidizing agents, and the balance of water.

The water soluble strongly basic components may comprise any number of bases. Preferably, the water soluble strong base is quaternary ammonium hydroxide, such as tetraalkyl ammonium hydroxides (including hydroxyl- and alkoxy-containing alkyl groups generally from 1 to 4 carbon atoms in the alkyl or alkoxy group) or a metal hydroxide such as potassium hydroxide. The most preferable of these bases are tetramethyl ammonium hydroxide, tetrabutyl ammonium hydroxide, and potassium hydroxide. Examples of other usable quaternary ammonium hydroxides include: benzyltrimethyl ammonium hydroxide, trimethyl-2-hydroxyethyl ammonium hydroxide (choline), trimethyl-3-hydroxypropyl ammonium hydroxide, trimethyl-3-hydroxybutyl ammonium hydroxide, trimethyl-4-hydroxybutyl ammonium hydroxide, triethyl-2-hydroxyethyl ammonium hydroxide, tripropyl-2-hydroxyethyl ammonium hydroxide, tributyl-2-hydroxyethyl ammonium hydroxide, dimethylethyl-2-hydroxyethyl ammonium hydroxide, dimethyldi(2-hydroxyethyl) ammonium hydroxide, monomethyltri(2-hydroxyethyl) ammonium hydroxide, tetraethyl ammonium hydroxide, tetrapropyl ammonium hydroxide, monomethyltriethyl ammonium hydroxide, monomethyltripropyl ammonium hydroxide, monomethyltributyl ammonium hydroxide, monoethyltrimethyl ammonium hydroxide, monoethyltributyl ammonium hydroxide, and the like and mixtures thereof.

The water soluble organic amine components may comprise any number of amines. Preferably, the water soluble organic amine is 2-aminoethanol, 2-(2-aminoethylamino)ethanol, or 4-(3-aminopropyl)morpholine. Examples of other usable water soluble organic amines include: alkanolamines such as 1-amino-2-propanol, 1-amino-3-propanol, 2-(2-aminoethoxy)ethanol, 2-methylaminoethanol, 2-dimethylaminoethanol, diethanolamine, triethanolamine, tris(hydroxymethyl)-aminomethane, 2-dimethylamino-2-methyl-1-propanol, and the like, and other strong organic bases such as guanidine, 1,3-pentanediamine, 4-aminomethyl-1,8-octanediamine, 2-aminoethylpiperazine, 2-(2-aminoethylamino)ethylamine, 1,2-diaminocyclohexane, tris(2-aminoethyl)amine, and 2-methyl-1,5-pentanediamine and mixtures thereof.

The water soluble oxidizing agent component may comprise any number of oxidants. These oxidants facilitate the removal of organic coatings such as photoresists. Oxidizing agents also help to maintain a protective oxide surface layer on any sensitive materials present, particularly solder and silicon. Preferably, the water soluble oxidizing agent is hydrogen peroxide or N-methylmorpholine-N-oxide. Hydrogen peroxide is preferred because of its low cost, its availability as a high purity reagent throughout the world, and because its only decomposition products are the environmentally friendly substances water and oxygen gas. Examples of other water soluble oxidizing agents useful for this purpose are: organic peracids, urea peroxide, and organic or inorganic perborates, percarbonates, or persulfates and mixtures thereof.

These compositions may also be formulated with suitable water soluble corrosion inhibitors to further reduce the etch rates for any sensitive metals present, particularly aluminum or copper. Typical examples of water soluble corrosion inhibitors useful for this purpose are: resorcinol, triazoles, tetrazoles, 8-hydroxyquinoline, benzoic acid, and phthalic acids; and salts of the acids, anhydrides of the acids, or esters of the acids; and mixtures thereof. Additional water soluble corrosion inhibitors suitable for this purpose include boric acid, base soluble borate and silicate salts, polyhydroxy alcohols, such as ethylene glycol, propylene glycol, glycerol, and 1-hydroxyalkyl-2-pyrrolidones such as 1-(2-hydroxyethyl)-2-pyrrolidone and mixtures thereof.

These compositions may also contain any suitable water-soluble amphoteric, non-ionic, cationic, or anionic surfactant. The addition of a surfactant reduces the surface tension of the formulation and improves the wetting of the surface to be cleaned and therefore improves the cleaning action of the composition.

Amphoteric surfactants useful in these compositions include betaines and sulfobetaines such as alkyl betaines, amidoalkyl betaines, alkyl sulfobetaines, and aminoalkyl sulfobetaines; aminocarboxylic acid derivatives such as amphoglycinates, amphopropionates, amphodiglycinates, and amphodipropionates; iminodiacids such as alkoxyalkyl iminodiacids; fluorinated alkyl amphoterics; and mixtures thereof.

Non-ionic surfactants useful in these compositions include acetylenic diols, ethoxylated acetylenic diols, fluorinated alkyl alkoxylates, fluorinated alkylesters, fluorinated polyoxyethylene alkanols, aliphatic acid esters of polyhydric alcohols, polyoxyethylene monoalkyl ethers, polyoxyethylene diols, and siloxane type surfactants; and mixtures thereof.

Anionic surfactants useful in these compositions include carboxylates, N-acylsarcosinates, sulfonates, fluoroalkyl sulfonates, sulfonic acids, sulfates, and mono- and diesters of orthophosphoric acid such as decyl phosphate, and mixtures thereof. Preferably, the anionic surfactants are metal-ion free sulfonic acids and sulfonic acid salts. Most preferably the anionic surfactants are dodecylbenzenesulfonic acid and ammonium lauryl sulfate.

Cationic surfactants useful in the compositions include amine ethoxylates, dialkyldimethyl ammonium salts, dialkylmorpholinum salts, alkylbenzyldimethyl ammonium salts, alkyltrimethyl ammonium salts, and alkylpyridinium salts, and mixtures thereof.

These compositions may also be formulated with suitable water soluble metal chelating agents to increase the capacity of the formulation to retain metals in solution and to enhance the dissolution of metallic residues on the surface, such as post-etch or post-CMP residues on microelectronic substrates or nanostructures. Metal chelating agents are also useful for stabilizing the water soluble oxidizing agents present in the compositions, particularly hydrogen peroxide. Typical examples of water soluble chelating agents useful for this purpose, known to those skilled in the art, include the following organic acids and their isomers and salts; ethylenediaminetetraacetic acid (EDTA), butylenediaminetetraacetic acid, cyclohexane-1,2-diaminetetraacetic acid (CyDTA), diethylenetriaminepentaacetic acid (DETPA), ethylenediaminetetraproprionic acid, (hydroxyl)ethylenediaminetriacetic acid (HEDTA), N,N,N′,N′-ethylenediaminetetra (methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrilotriacetic acid (NTA), citric acid, tartaric acid, gluconic acid, saccharic acid, glyceric acid, phthalic acid, maleic acid, mandelic acid, malonic acid, lactic acid, salicylic acid, and cystine. Preferred chelating agents are aminocarboxylic acids such as EDTA and CyDTA. Chelating agents of this class have a high affinity for the aluminum-containing residues typically found on microelectronic structures such as metal lines, vias, and pads, or nanostructures after dry etching and plasma ashing. The preferred chelating agent for hydrogen peroxide stabilization is CyDTA, which is highly valued because of its oxidation resistance and high affinity for peroxide destabilizing ions such as iron. Additional preferred chelating agents are the multi-carboxylic acids such as citric acid which have a high affinity for copper-containing residues typically found on the surface of a microelectronic substrate or nanostructures after a CMP process or in vias, trenches, or nanostructures after dry etching and plasma ashing.

The present invention provides a user with a cleaning solution for removing an imaged thick dry film photoresist that remains after the deposition of solder bumps and subsequent heating to affect solder reflow. The composition of the cleaning solution consists of 0.1 to 10% by weight quaternary ammonium hydroxide, 0.1 to 20% by weight alkanolamine, 0.1 to 10% hydrogen peroxide, balance water. Preferably, the pH of the solution is greater than 12.

Another composition of the present invention presents a user with a cleaning solution for removing thick photoresist that remains after the deposition of solder bumps onto imaged “under bump metal” solder pads. The composition of the cleaning solution consists of 0.1 to 10% by weight potassium hydroxide, 0.1 to 20% by weight alkanolamine, 0.1 to 10% N-methylmorpholine-N-oxide, balance water. Preferably, the pH of the solution is greater than 12.

Another cleaning solution according to the present invention is useful for removing up to 2.5 μm of hard baked photoresist from tetraethylorthosilicate (TEOS) dielectric. This composition consists of 0.1 to 10% by weight quaternary ammonium hydroxide, 0.1 to 20% by weight alkanolamine, 0.5 to 5% hydrogen peroxide, balance water. Preferably, the pH of the solution is greater than 12.

Still another cleaning solution according to the present invention is useful for removing photoresist implanted with B⁺ and As⁺ ions consisting of 0.1 to 10% by weight quaternary ammonium hydroxide, 0.1 to 20% by weight alkanolamine, 0.1 to 5% hydrogen peroxide, balance water. Preferably, the pH of the solution is greater than 12.

Other compositions according to the present invention are used to remove organic impurities (e.g., from copper surfaces typically present during the manufacture of integrated circuits, or heterocyclic corrosion inhibitors such as benzotriazole and the like).

Compositions according to the present invention are used to clean multi-crystalline silicon surfaces subsequent to phosphorous doping. Silicon cleaned in this way yields photovoltaic cells with higher efficiency.

Compositions according to the present invention are used to remove grease and oils, sooty deposits and other impinged soils from a wide variety of metallic surfaces, especially aircraft exteriors.

Compositions according to the present invention may be used at various concentrations to clean microelectronic substrates containing integrated circuits or such substrates that require cleaning before the integrated circuits are fabricated. When integrated circuits are present, the compositions remove metallic and organic contaminates, including particles, without damaging the integrated circuits. These compositions are particularly useful for the removal of organic coatings, e.g., photoresists. Multiple fabrication steps requiring the application, patterning, and removal of photoresists are typically used to manufacture integrated circuits. These compositions are useful for the removal of the gamut of photoresist chemistries including the highly implanted positive photoresists that occur during IC gate fabrication and ranging to the very thick negative photoresists used for solder bump placement.

When used for cleaning microelectronic substrates or nanostructures, a contaminated substrate is exposed to compositions according to the invention for a time and at a temperature sufficient to clean unwanted contaminates from the substrate surface, rinsed with water, and dried. The substrate can then be used for its intended purpose.

A preferred method uses a bath or spray to expose the substrate to the composition. Bath or spray cleaning times are generally 1 minute to 60 minutes. Bath or spray cleaning temperatures are generally 10° C. to 85° C., preferably 20° C. to 75° C. The water soluble oxidizing agent may be injected at the point of use to preserve oxidizing ability at elevated temperatures.

If required, the rinse times are generally 10 seconds to 5 minutes at room temperature, preferably 30 seconds to 2 minutes at room temperature. Preferably de-ionized water is used to rinse the substrates although the use of an intermediate 2-propanol rinse may also be useful.

If required, drying the substrates can be accomplished using any combination of air-evaporation, heat, spinning, pressurized gas, or Marangoni effect driers. A preferred drying technique is spinning under a filtered inert gas flow, such as nitrogen, for a period of time until the wafer substrate is dry.

Use of compositions according to the present invention provides effective cleaning of semiconductor wafer substrates or nanostructures that have been previously oxygen plasma ashed to remove bulk photoresist, particularly wafer substrates containing a silicon, silicon dioxide, silicon nitride, silicon carbide, tungsten, tungsten alloy, titanium, titanium alloy, tantalum, tantalum alloy, copper, copper alloy, aluminum, or aluminum alloy film, and removes unwanted metallic and organic contaminates without causing unacceptable corrosion to the substrates.

Use of compositions according to the present invention provides effective cleaning of semiconductor substrates or nano-structures that have been subjected to chemical mechanical polishing (CMP) and are contaminated with polishing slurry particles and residues. A variety of conventional cleaning tools, including Verteq single wafer megasonic Goldfinger, DDS (double-sided scrubbers), single wafer spin wash, and megasonic batch wet bench systems may be utilized effectively.

Concentrates of compositions according to the present invention may be prepared by reducing the percentage of water noted in the composition described above. The resulting concentrates can later be diluted with an amount of water necessary to produce the desired cleaning compositions.

The following examples illustrate specific embodiments of the invention described in this document. As would be apparent to skilled artisans, various changes and modifications are possible and are contemplated within the scope of the invention described.

The components listed in Table I were combined with stirring to give each of the 19 homogeneous compositions. The compositions of Examples 1-19 can optionally be formulated to include corrosion inhibitors, surfactants, or chelating agents.

TABLE I

| Example | Formulation |
|---|---|
| 1a | 4.5 g 2-Aminoethanol (4.5%) |
| | 2.5 g Tetramethylammonium hydroxide (2.5%) |
| | 1.0 g Hydrogen peroxide (1.0%) |
| | 92 g water (92%) |
| 1b | 4.5 g 2-Aminoethanol (4.5%) |
| | 2.5 g Tetramethylammonium hydroxide (2.5%) |
| | 93 g water (93%) |
| 2 | 4.5 g 2-Aminoethanol (4.5%) |
| | 2.5 g Tetramethylammonium hydroxide (2.5%) |
| | 0.3 g Hydrogen peroxide (0.3%) |
| | 92.7 g water (92.7%) |
| 3 | 4.5 g 2-Aminoethanol (4.5%) |
| | 2.5 g Tetramethylammonium hydroxide (2.5%) |
| | 0.5 g Hydrogen peroxide (0.5%) |
| | 92.5 g water (92.5%) |
| 4 | 4.3 g 2-Aminoethanol (4.3%) |
| | 2.4 g Tetramethylammonium hydroxide (2.4%) |
| | 2.4 g Hydrogen peroxide (2.4%) |
| | 90.9 g water (90.9%) |
| 5 | 4.5 g 2-Aminoethanol (4.3%) |
| | 2.5 g Tetramethylammonium hydroxide (2.4%) |
| | 4.0 g N-Methylmorpholine-N-oxide (3.9%) |
| | 93 g water (89.4%) |
| 6 | 4.5 g 2-Aminoethanol (2.2%) |
| | 2.5 g Tetramethylammonium hydroxide (1.2%) |
| | 4.0 g N-Methylmorpholine-N-oxide (1.9%) |
| | 197 g water (94.7%) |
| 7 | 4.5 g 2-Aminoethanol (0.9%) |
| | 2.5 g Tetramethylammonium hydroxide (0.5%) |
| | 4.0 g N-Methylmorpholine-N-oxide (0.8%) |
| | 509 g water (97.8%) |
| 8 | 4.5 g 2-Aminoethanol (0.8%) |
| | 2.5 g Tetramethylammonium hydroxide (0.5%) |
| | 8.0 g N-Methylmorpholine-N-oxide (1.4%) |
| | 545 g water (97.3%) |
| 9 | 4.5 g 2-Aminoethanol (0.2%) |
| | 2.5 g Tetramethylammonium hydroxide (0.1%) |
| | 4.0 g N-Methylmorpholine-N-oxide (0.2%) |
| | 2170 g water (99.5%) |
| 10 | 4.5 g 2-Aminoethanol (4.5%) |
| | 10 g Potassium hydroxide (10%) |
| | 1.0 g N-Methylmorpholine-N-oxide (1.0%) |
| | 84.5 g water (84.5%) |
| 11 | 0.1 g 2-Aminoethanol (0.1%) |
| | 10 g Potassium hydroxide (10%) |
| | 1.0 g N-Methylmorpholine-N-oxide (1.0%) |
| | 88.9 g water (88.9%) |
| 12 | 20 g 2-Aminoethanol (20%) |
| | 1.0 g Potassium hydroxide (1.0%) |
| | 1.0 g N-Methylmorpholine-N-oxide (1.0%) |
| | 78 g water (78%) |
| 13 | 20 g 2-Aminoethanol (20%) |
| | 1.0 g Potassium hydroxide (1.0%) |
| | 0.1 g N-Methylmorpholine-N-oxide (0.1%) |
| | 78.9 g water (78.9%) |
| 14 | 4.5 g 2-Aminoethanol (4.5%) |
| | 2.5 g Tetramethylammonium hydroxide (2.5%) |
| | 10 g N-Methylmorpholine-N-oxide (10%) |
| | 83 g water (83%) |
| 15 | 4.5 g 2-(2-Aminoethylamino)ethanol (4.5%) |
| | 10 g Potassium hydroxide (10%) |
| | 1.0 g N-Methylmorpholine-N-oxide (1.0%) |
| | 84.5 g water (84.5%) |
| 16 | 4.5 g 1-amino-2-propanol (4.5%) |
| | 10 g Potassium hydroxide (10%) |
| | 1.0 g N-Methylmorpholine-N-oxide (1.0%) |
| | 84.5 g water (84.5%) |
| 17 | 4.5 g 4-(3-Aminopropyl)morpholine (4.5%) |
| | 10 g Potassium hydroxide (10%) |
| | 1.0 g N-Methylmorpholine-N-oxide (1.0%) |
| | 84.5 g water (84.5%) |
| 18 | 4.5 g 2-Aminoethanol (4.5%) |
| | 7.1 g Tetrabutylammonium hydroxide (7.1%) |
| | 1.0 g N-Methylmorpholine-N-oxide (1.0%) |
| | 87.4 g water (87.4%) |
| 19 | 4.5 g 2-Aminoethanol (4.5%) |
| | 4.6 g Benzyltrimethylammonium hydroxide (4.6%) |
| | 1.0 g N-Methylmorpholine-N-oxide (1.0%) |
| | 89.9 g water (89.9%) |

### Example 20

### Removal of Thick Photopolymer from Solder Bumps

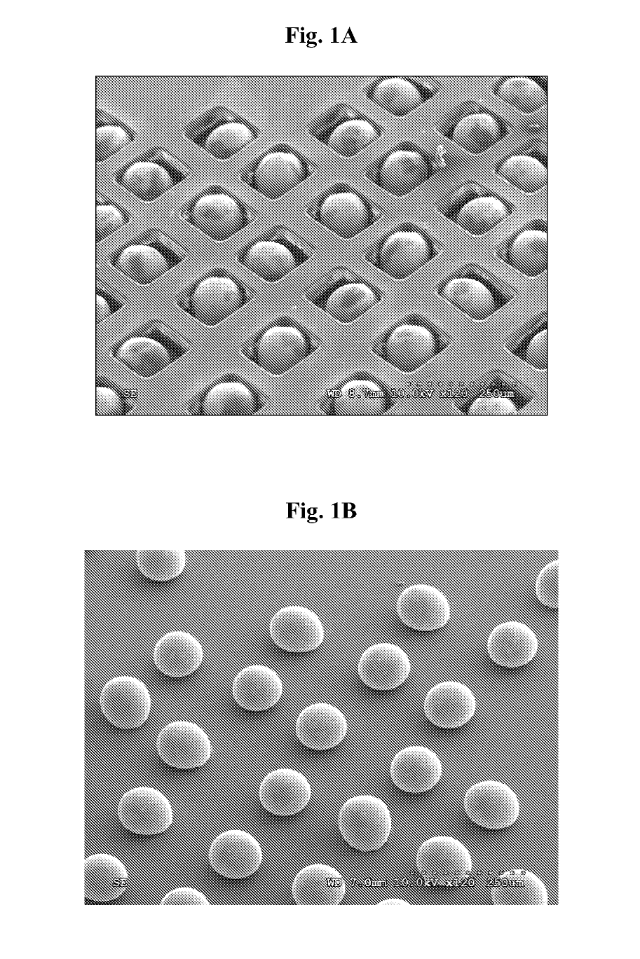

A 75 μm thick film of Shipley GA-30 dry film photopolymer was laminated to a silicon wafer and patterned. A tin-lead eutectic solder was deposited into the opened features and subsequently heated to reflow. This heating step hardened the photopolymer rendering it difficult to remove using typical solvent mixtures. FIG. 1A is a SEM micrograph of the resulting solder bumps before cleaning. FIG. 1B is a SEM micrograph of the solder bumps after cleaning with the composition according to Example 1a at 65° C. for 30 minutes to remove the photopolymer, followed by a water rinse. The photopolymer was completely removed without affecting the solder bumps. Cleaning with the composition according to Example 1b at 65° C. for 10 minutes followed by a water rinse removed the photopolymer but also removed the solder bumps. Thus without the hydrogen peroxide component, the composition was too aggressive, removing the desired solder bumps as well as the photopolymer.

An etch rate for the composition according to Example 1a on pure tin foil at a temperature of 65° C. was determined to be 4 Å/minute, for the composition from Example 1b the rate was 19 Å/minute. Thus the addition of hydrogen peroxide reduces the solder (63% tin) etch rate enough to allow retention of the solder bumps even after 30 minutes of processing time.

### Example 21

### Removal of Implanted Photoresist

Photoresist was applied to a silicon wafer and patterned in the usual way. The patterned wafer was implanted at about 30 KeV with 10e13 of B⁺ and As⁺ ions resulting in a very difficult to remove hardened photoresist. Treatment of pieces of this wafer with either the composition according to Example 2 or the composition according to Example 1b at 65° C. for 10 minutes followed by a water rinse completely removed the hardened photoresist. However the composition according to Example 1b caused considerable etching and roughening of the cleaned silicon surface whereas the composition according to Example 2 resulted in a clean and smooth surface.

An etch rate for the composition according to Example 2 on a silicon wafer at the cleaning temperature of 65° C. was determined to be 0 Å/minute, for the composition according to Example 1b the rate was 8 Å/minute. Thus the addition of hydrogen peroxide eliminated silicon etching protecting the wafer from damage.

### Example 22

### Removal of Thin Photoresist

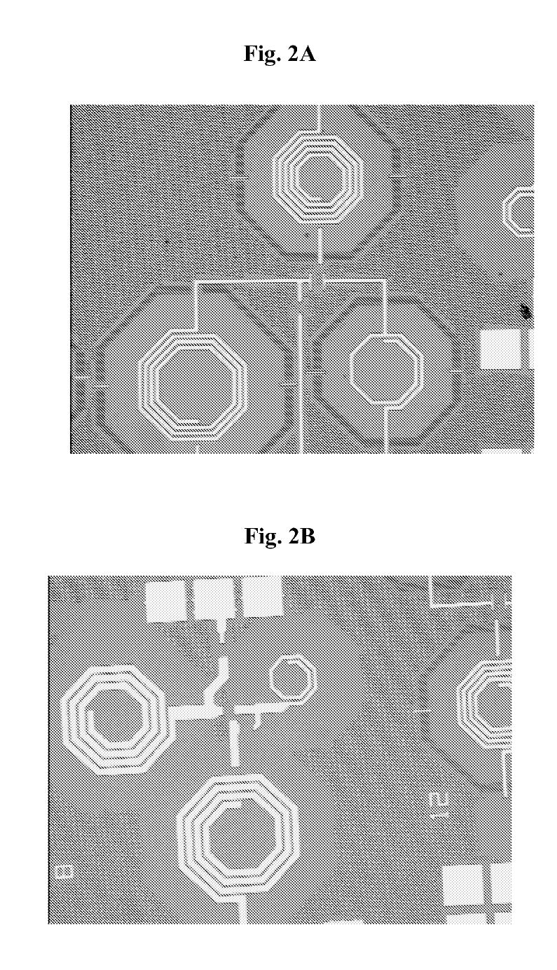

A silicon wafer was treated to give a 700 nm thick tetraethylorthosilicate (TEOS) film which was topped with 200 nm of SiN then 1650 nm more of TEOS. A 2.4 μm thick film of photoresist was spun onto this surface, baked and patterned. This process hardened the photoresist rendering it impossible to remove using typical solvent mixtures. FIG. 2A is an optical micrograph of the resulting pattern before cleaning. FIG. 2B is an optical micrograph of the pattern after cleaning with a composition according to Example 3 at 75° C. for 10 minutes followed by water rinsing. This treatment completely removed the hardened photoresist. Cleaning with a composition according to Example 1b at 75° C. for 20 minutes had no effect on the photoresist. Thus the presence of an oxidizing agent was necessary to remove the hardened photoresist. The composition according to Example 4, containing 2.4% of hydrogen peroxide, was also effective for removing the photoresist from these patterns.

### Example 23

### Removal of Thick Photopolymer from Solder Bumps Deposited onto UBM (Under Bump Metal)

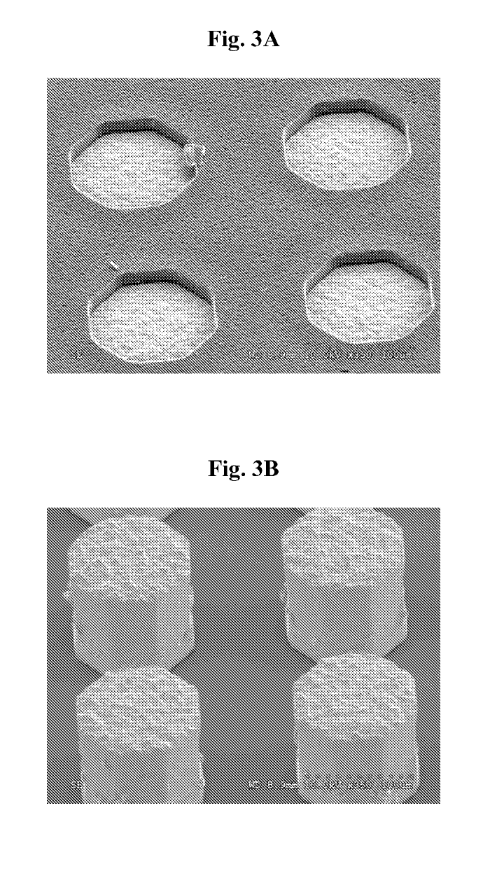

A 120 μm negative dry film photophotoresist was laminated to a copper plated (5000 Å of Cu) silicon wafer and patterned. Eutectic solder bumps were deposited into the opened features and subsequently heated to reflow. This heating step hardened the photopolymer rendering it difficult to remove using typical solvent mixtures. FIG. 3A is a SEM micrograph of the resulting solder bumps before cleaning. FIG. 3B is a SEM micrograph of the solder bumps after cleaning with the composition according to Example 1a at 55° C. for 10 minutes followed by a 2-propanol intermediate rinse then rinsing with deionized water. The photopolymer was completely removed without affecting the solder bumps.

Additional formulations were similarly tested using pieces of the wafer used in Example 23 containing eutectic solder on copper UBM. The results are listed in Table II.

TABLE II

| | Stripping | | | |
|---|---|---|---|---|
| | Temperature | Stripping | Photoresist | Solder Bump |
| Composition* | (° C.) | Time (min.) | Removal | Retention |
| 1a | 55-65 | 10 | Satisfactory | Retained |
| 1a | 45 | 30 | Satisfactory | Retained |
| 1b | 55 | 10-20 | Poor | Retained |
| 5 | 45 | 20 | Good | Retained |
| 6 | 45 | 20-40 | Good | Retained |
| 7 | 45 | 40 | Good | Retained |
| 8 | 45 | 40 | Good | Retained |
| 9 | 65 | 60 | Satisfactory | Retained |
| 10 | 65 | 60 | Excellent | Retained |
| 11 | 65 | 60 | Good | Retained |
| 12 | 65 | 60 | Satisfactory | Retained |
| 13 | 65 | 60 | Good | Retained |
| 14 | 65 | 60 | Satisfactory | Retained |
| 15 | 65 | 60 | Good | Retained |
| 16 | 65 | 60 | Good | Retained |
| 17 | 65 | 60 | Excellent | Retained |
| 18 | 65 | 60 | Good | Retained |
| 19 | 65 | 60 | Satisfactory | Retained |

*As set out in Table I

The foregoing results demonstrate the utility of a wide range of compositions according to the invention, including different water soluble strongly basic components, different water soluble organic amines, and different water soluble oxidizing agents as well as a range of concentrations for these components. As set out in Table II, compositions according to Example 1b, no oxidizing agent is present, the result is “poor” photoresist removal demonstrating that the oxidizing component is necessary.

### Example 24

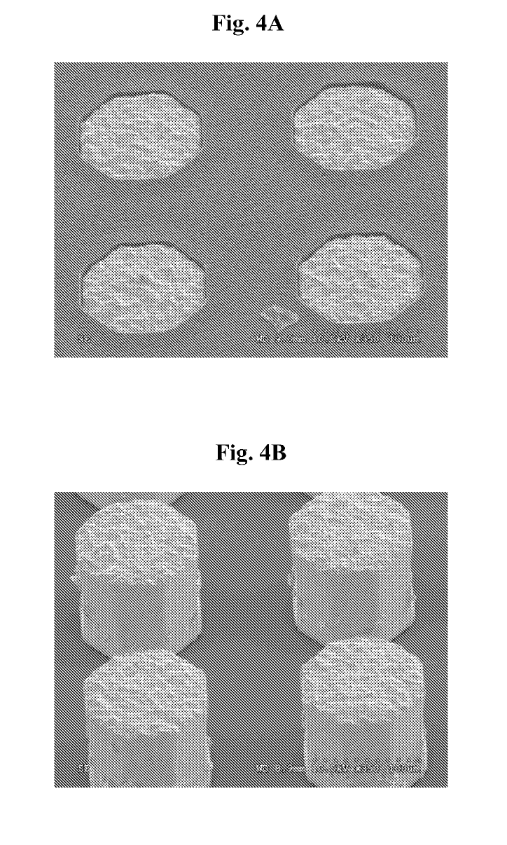

A 120 μm negative dry film photophotoresist was laminated to a copper plated silicon wafer and patterned as in Example 23. In this example high lead (greater than 37% lead) solder bumps were deposited into the opened features and subsequently heated to reflow. FIG. 4A is a SEM micrograph of the resulting solder bumps before cleaning. FIG. 4B is a SEM micrograph of the solder bumps after cleaning with the composition according to Example 1a at 55° C. for 10 minutes followed by a 2-propanol intermediate rinse then rinsing with deionized water. The photopolymer was completely removed without affecting the solder bumps.

Additional formulations were similarly tested using pieces of the wafer of Example 24 containing high lead solder bumps on copper UBM. The results are listed in Table III.

TABLE III

| | Stripping | | | |
|---|---|---|---|---|
| Formulation | Temperature | Stripping | Photoresist | Solder Bump |
| Example | (° C.) | Time (min.) | Removal | Retention |
| 1a | 55-65 | 10 | Satisfactory | Retained |
| 1a | 45 | 30 | Satisfactory | Retained |
| 1b | 55 | 10-20 | Poor | Retained |
| 5 | 45 | 20 | Satisfactory | Retained |
| 6 | 45 | 40 | Satisfactory | Retained |
| 7 | 45 | 40 | Satisfactory | Retained |
| 8 | 45 | 40 | Satisfactory | Retained |
| 9* | | | | |
| 10 | 65 | 60 | Good | Retained |
| 11 | 65 | 60 | Good | Retained |
| 12 | 65 | 60 | Satisfactory | Retained |
| 13 | 65 | 60 | Good | Retained |
| 14 | 65 | 60 | Satisfactory | Retained |
| 15 | 65 | 60 | Satisfactory | Retained |
| 16 | 65 | 60 | Satisfactory | Retained |
| 17 | 65 | 60 | Good | Retained |
| 18 | 65 | 60 | Good | Retained |
| 19 | 65 | 60 | Satisfactory | Retained |

*Not tested in Example 24

The foregoing examples also demonstrate the utility of a wide range of compositions including different water soluble strongly basic components, water soluble organic amines, and water soluble oxidizing agents as well as a range of concentrations for these components. Compositions according to Example 1b contain no oxidizing agent. The resulting “poor” photoresist removal result demonstrates that the oxidizing component is necessary.

### Example 25

### Compatibility of Amines with Oxidizing Agents

A composition according to Example 1b containing 4.5% of the amine 2-aminoethanol was treated with 0.5% of 50% aqueous hydrogen peroxide. The mixture was immediately assayed for hydrogen peroxide by titrating with standard potassium permanganate solution using “Method for High Level Peroxide Concentrations” published online by FMC Chemicals, Inc. at their OxyPure Online website. The analytical result was the expected 0.25% hydrogen peroxide. After aging for two days at room temperature, the assay remained 0.23% hydrogen peroxide demonstrating the stability of the amine-hydrogen peroxide mixture.

Additional stability can be achieved by adding 0.1% of the chelating agent cyclohexane-1,2-diaminetetraacetic acid to the composition according to Example 1b. Treating such a mixture with 0.6% of 50% aqueous hydrogen peroxide gave the expected 0.30% hydrogen peroxide assay. The hydrogen peroxide content was unchanged after one day and had decreased only moderately to 0.23% hydrogen peroxide after eight days at room temperature.

A stainless steel bath containing 3.3 kg of a composition from Example 1a was heated to 55° C. and held for a total of five hours. The mixture was analyzed for 2-aminoethanol content by titrating with 1N hydrochloric acid. The assay the beginning of the heating period was 4.67% 2-aminoethanol, at the end, 4.68% 2-aminoethanol. This further demonstrates the unexpected stability of the amine-hydrogen peroxide mixture.

Having thus described our invention what is desired to be secured by Letters Patent of the United States is set forth in the appended claims.

What is claimed is:

1. A liquid cleaning composition for removing particles, organic contamination, photoresist, post-ash residue, coatings, and other materials from metal and silicon surfaces containing a major portion of water with an effective amount of a water soluble strong base, an effective amount of water soluble organic amine, and an effective amount of a water soluble oxidizing agent.

2. A liquid cleaning composition for removing particles, organic contamination, photoresist, post-ash residue, coatings, and other materials from metal and silicon surfaces comprising 0.1 to 10% by volume of a water soluble strong base, 0.1 to 20% by volume water soluble organic amine, 0.1 to 10% by volume water soluble oxidizing agent, balance water

3. A composition according to claim 1 wherein the water soluble amine is present in an amount form 1 to 10% by volume.

4. A composition according to claim 1 wherein the base is selected from the group consisting of tetramethylammonium hydroxide, potassium hydroxide, benzyltrimethylammonium hydroxide and tetrabutylammonium hydroxide and mixtures thereof.

5. A composition according to claim 1 where the amine is selected from the group consisting of 2-aminoethanol, 2-(2-aminoethylamino)ethanol, 4-(3-aminopropyl)morpholine, 1-amino-2-propanol and mixtures thereof.

6. A composition according to claim 1 wherein the oxidizing agent is selected from the group consisting of hydrogen peroxide and N-methylmorpholine-N-oxide and mixtures thereof.

7. A composition according to claim 1 wherein the water soluble strong base produces a pH greater than 10.

8. A composition according to claim 1 where the water soluble strong base produces a pH greater than 12.

9. A composition according to claim 1 including addition of optional components selected from the group consisting of corrosion inhibitors, surfactants, chelating agents and mixtures thereof.

10. A composition according to claim 6 wherein the chelating agent is cyclohexane-1,2-diaminetetraacetic acid.

11. A liquid cleaning composition according to claim 1 wherein the strong base is selected from the group consisting of sodium hydroxide, potassium hydroxide, benzyltrimethyl ammonium hydroxide, trimethyl-2-hydroxyethyl ammonium hydroxide (choline), trimethyl-3-hydroxypropyl ammonium hydroxide, trimethyl-3-hydroxybutyl ammonium hydroxide, trimethyl-4-hydroxybutyl ammonium hydroxide, triethyl-2-hydroxyethyl ammonium hydroxide, tripropyl-2-hydroxyethyl ammonium hydroxide, tributyl-2-hydroxyethyl ammonium hydroxide, dimethylethyl-2-hydroxyethyl ammonium hydroxide, dimethyldi(2-hydroxyethyl) ammonium hydroxide, monomethyltri(2-hydroxyethyl) ammonium hydroxide, tetraethyl ammonium hydroxide, tetrapropyl ammonium hydroxide, monomethyltriethyl ammonium hydroxide, monomethyltripropyl ammonium hydroxide, monomethyltributyl ammonium hydroxide, monoethyltrimethyl ammonium hydroxide, monoethyltributyl ammonium hydroxide, and the like and mixtures thereof, the water soluble amine is selected from the group consisting of 2-aminoethanol, 2-(2-aminoethylamino)ethanol, 4-(3-aminopropyl)morpholine, 1-amino-2-propanol, 1-amino-3-propanol, 2-(2-aminoethoxy)ethanol, 2-methylaminoethanol, 2-dimethylaminoethanol, diethanolamine, triethanolamine, tris(hydroxymethyl)-aminomethane, 2-dimethylamino-2-methyl-1-propanol, 1,3-pentanediamine, 4-aminomethyl-1,8-octanediamine, 2-aminoethylpiperazine, 2-(2-aminoethylamino)ethylamine, 1,2-diaminocyclohexane, tris(2-aminoethyl)amine, and 2-methyl-1,5-pentanediamine and mixtures thereof, and the water soluble oxidizing agent is selected from the group consisting of hydrogen peroxide or N-methylmorpholine-N-oxide, organic peracids, urea peroxide, and organic or inorganic perborates, percarbonates, or persulfates and mixtures thereof.

12. A liquid cleaning composition according to claim 6 wherein the water soluble corrosion inhibitor is selected from the group consisting of resorcinol, triazoles, tetrazoles, 8-hydroxyquinoline, benzoic acid, and phthalic acids, salts of the acids, anhydrides of the acids, esters of the acids, boric acid, base soluble borate and silicate salts, polyhydroxy alcohols, such as ethylene glycol, propylene glycol, glycerol, and 1-hydroxyalkyl-2-pyrrolidones such as 1-(2-hydroxyethyl)-2-pyrrolidone and mixtures thereof, the surfactants are selected from the group consisting of alkyl betaines, amidoalkyl betaines, alkyl sulfobetaines, and aminoalkyl sulfobetaines; aminocarboxylic acid derivatives such as amphoglycinates, amphopropionates, amphodiglycinates, and amphodipropionates, iminodiacids such as alkoxyalkyl iminodiacids; fluorinated alkyl amphoterics, and mixtures thereof, acetylenic diols, ethoxylated acetylenic diols, fluorinated alkyl alkoxylates, fluorinated alkylesters, fluorinated polyoxyethylene alkanols, aliphatic acid esters of polyhydric alcohols, polyoxyethylene monoalkyl ethers, polyoxyethylene diols, and siloxane type surfactants, and mixtures thereof, carboxylates, N-acylsarcosinates, sulfonates, fluoroalkyl sulfonates, sulfonic acids, sulfates, and mono- and diesters of orthophosphoric acid such as decyl phosphate, and mixtures thereof, metal-ion free sulfonic acids and sulfonic acid salts, dodecylbenzenesulfonic acid and ammonium lauryl sulfate, amine ethoxylates, dialkyldimethyl ammonium salts, dialkylmorpholinum salts, alkylbenzyldimethyl ammonium salts, alkyltrimethyl ammonium salts, and alkylpyridinium salts, and mixtures thereof, and the chelating agent is selected from the group consisting of ethylenediaminetetraacetic acid (EDTA), butylenediaminetetraacetic acid, cyclohexane-1,2-diaminetetraacetic acid (CyDTA), diethylenetriaminepentaacetic acid (DETPA), ethylenediaminetetraproprionic acid, (hydroxyl)ethylenediaminetriacetic acid (HEDTA), N,N,N′,N′-ethylenediaminetetra (methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrilotriacetic acid (NTA), citric acid, tartaric acid, gluconic acid, saccharic acid, glyceric acid, phthalic acid, maleic acid, mandelic acid, malonic acid, lactic acid, salicylic acid, and cystine and mixtures thereof.

13. A method for cleaning contaminants being one of, particles, organic contamination, post-ash residue, coatings and other materials from metal and silicon surfaces comprising the steps of:
exposing a surface coating of one or more of said contaminants to a composition consisting of 0.1 to 10% by volume of a strong base, 0.1 to 20% by volume water soluble organic amine, 0.1 to 10% by volume water soluble oxidizing agent, balance water at a temperature of from 110° C. to 85° C. for a period of time from ten seconds to five minutes; and
rinsing said surface in de-ionized water.

14. A method according to claim 13 wherein an optional drying step is included after said rinsing step.

15. A method according to claim 13 including the step of controlling the composition to have a pH greater than 10.

16. A method according to claim 13 including the step of controlling the composition to have H greater than 12.
